(19) United States
(12) Patent Application Publication
(10) Pub. No.: US 2009/0029222 A1
(43) Pub. Date: Jan. 29, 2009

(54) Fuel cell with structured gas diffusion layer and manufacturing method of gas diffusion layer

(76) Inventors: Joongmyeon Bae, Daejeon (KR); Dongryul Lee, Daejeon (KR)

Correspondence Address: CLARK & BRODY, 1090 VERMONT AVENUE, NW, SUITE 250, WASHINGTON, DC, 20005, US

(21) Appl. No.: 12/219,489

(22) Filed: Jul. 23, 2008

(30) Foreign Application Priority Data
Jul. 24, 2007 (KR) 10-2007-0073968

(51) Int. Cl. H01M 8/10; G03F 7/20

(52) U.S. Cl. 429/30; 430/323; 29/623.1; 264/299

(57) ABSTRACT

A cell for a fuel cell comprises an electrolyte layer, a catalyst layer and a gas diffusion layer formed to be contacted to both sides of the electrolyte layer, an anode contacting hydrogen, and a cathode contacting oxygen and air, cations being transferred through the electrolyte layer or the operating temperature being equal to or less than 100° C., characterized in that the cell for the fuel cell has hollow portions hollowed up and down inside the gas diffusion layer. The manufacturing method uses a mold having the specific pattern to form the hollow portion in the gas diffusion layer using the micro needle or the micro lens so that the diffusion resistance inside the gas diffusion layer is lowered, making it possible to smoothly move fuel and reactants through the hollow portion and the reaction is smoothly performed even in a situation where fuel partial pressure is low.

### TECHNICAL FIELD

The present invention relates to a gas diffusion layer, a manufacturing method thereof, and a fuel cell including a gas diffusion layer manufactured by the method, capable of improving a performance of the fuel cell by forming hollow portions in the gas diffusion layer to smoothly move fuel and byproduct.

### BACKGROUND ART

A fuel cell, which is a cell directly converting chemical energy produced by oxidation into electrical energy, is a new next-generation eco-friendly energy technology generating electrical energy from materials abundantly existing on earth, such as hydrogen, oxygen.

The fuel cell supplies oxygen to a cathode and supplies hydrogen to an anode to perform electrochemical reaction in the form of electrolysis reverse reaction on water, thereby producing electricity, heat, and water. As a result, the fuel cell produces electrical energy at high efficiency without leading to pollution.

Such a fuel cell has various advantages that it is free from a limitation of Carnot Cycle acting as a limit in a conventional heat engine so that its efficiency can be increased above 40%, it discharges only water as the discharge materials as described above so that there is no a risk of pollution, and it does not need mechanically moving parts so that it can be compacted and does not generate noise, or the like. Therefore, various technologies and studies associated with the fuel cell have actively been progressed.

Six kinds of fuel cells, such as a phosphoric acid fuel cell (PAFC), a molten carbonate fuel cell (MCFC), a solid oxide fuel cell (SOFC), a polymer electrolyte membrane fuel cell (PEMFC), a direct methanol fuel cell (DMFC), and an alkaline fuel cell (AFC) according to kinds of electrolytes have been put to practical use or has been in contemplation. Features of each fuel cell are arranged in the following table.

| | | | | | | |
|---|---|---|---|---|---|---|
| Division | PAFC | MCFC | SOFC | PEMFC | DMFC | AFC |
| Electrolyte | Phosphoric | Lithium | Zirconia | Hydrogen | Hydrogen | Potassium |
| | acid | carbonate/ | | Ion | Ion | hydroxide |
| | | Potassium | | exchange | exchange | |
| | | carbonate | | Membrane | Membrane | |
| Ion | Proton | Carbonate | Oxygen | Proton | Proton | Hydroxide |
| conductor | | ion | ion | | | ion |
| Operating | 200 | 650 | 1000 | <100 | <100 | <100 |
| temperature | | | | | | |
| (° C.) | | | | | | |
| Fuel | Hydrogen | Hydrogen, | Hydrogen, | Hydrogen | Methanol | Hydrogen |
| | | Carbon | Carbon | | | |
| | | monoxide | monoxide | | | |
| Fuel raw | City gas, | City gas, | City gas, | Methanol, | Methanol | Hydrogen |
| material | LPG | LPG, Coal | LPG | methane | | |
| | | | | gasoline, | | |
| | | | | Hydrogen | | |
| Efficiency | 40 | 45 | 45 | 45 | 30 | 40 |
| (%) | | | | | | |
| Output | 100-5000 | 1000-10000 | 1000-10000 | 1-1000 | 1-100 | 1-100 |
| range(kW) | | | | | | |
| Main use | Distributed | Large | Large | Power for | Portable | Power |
| | generation | scale | scale | transportation | power | supply |
| | type | generation | generation | | supply | for |
| | | | | | | Spaceship |
| Development | Verification- | Test- | Test- | Test- | Test- | Application |
| stage | commercialization | verification | verification | verification | verification | to |
| | | | | | | spaceship |

As can be appreciated from the table, each fuel cell has various output ranges and uses, etc. so that suitable fuel cells can be selected according to an object. Among others, since the polymer electrolyte membrane fuel cell (PEMFC) has advantages of even lower operating temperature, high efficiency and current density, and easy manufacture, as compared to other fuel cells, the effective value of the PEMFC is very large in that it is applicable to a power for transportation, that is, means such as a new concept car.

In a polymer electrolyte membrane fuel, cell Oxygen is supplied to the cathode and hydrogen is supplied to the anode. At this time, the reaction depends on the following formula.

Anode reaction: H₂→2H⁺+2e⁻

Cathode reaction: ½ O₂+2H⁺+2e→H₂O

The polymer electrolyte membrane fuel cell having the aforementioned features should smoothly move fuel (hydrogen and oxygen) supplied through the anode to a catalyst layer and should smoothly move current produced from the reaction of the catalyst layer and the electrolyte layer.

Therefore, a gas diffusion layer (GDL) of the anode is made of graphite with good electric conductivity to transfer current and to transfer fuel and byproduct (moisture) through pores therein.

FIG. 1(a) shows a microstructure of carbon cloth currently widely used as the gas diffusion layer and FIG. 1(b) shows a microstructure of carbon paper.

As shown in FIG. 1, the gas diffusion layer moves fuel and reactants through the pores therein, but the movement paths are irregularly entangled to make the movement resistance for diffusing fuel high so that fuel is smoothly not moved to the catalyst layer.

Also, it is difficult to expect the uniform performance of the fuel cell and in particular, large loss occurs in a high current region.

### DISCLOSURE OF THE INVENTION

The present invention proposes to solve the problems. It is an object of the present invention to provide a gas diffusion layer, a manufacturing method thereof, and a fuel cell including a gas diffusion layer manufactured by the method, capable of improving a performance of the fuel cell and expecting a uniform performance of the fuel cell by manufacturing the gas diffusion layer using a mold having a specific pattern or manufacturing the gas diffusion layer formed with a hollow portion using a micro needle or a micro lens to smoothly move fuel and reactants.

To achieve the objects, there is provided a cell for a fuel cell of the present invention comprising an electrolyte layer, a catalyst layer and a gas diffusion layer formed to be contacted to both sides of the electrolyte layer, an anode contacting hydrogen, and a cathode contacting oxygen and air, cations being transferred through the electrolyte layer or the operating temperature being equal to or less than 100° C., characterized in that the cell for the fuel cell has hollow portions hollowed up and down inside the gas diffusion layer.

Also, the hollow portion is formed in plurality. The hollow portion is inclinedly formed by a predetermined angle. In the cell for the fuel cell, the hollow portions are communicated with each other.

Meanwhile, as a manufacturing method of a gas diffusion layer, there is provided a manufacturing method of a gas diffusion layer in a fuel cell comprising the steps of: a) manufacturing a mold having a form corresponding to a hollow portion to form the hollow portion communicated up and down inside the gas diffusion layer; b) manufacturing the gas diffusion layer by putting and drying a material of the gas diffusion layer in the mold; and c) removing the mold.

Also, the step a) comprises the steps of: a-1) manufacturing a board forming the mold; a-2) forming an oxide film on the upper surface of the board; a-3) applying a photoresist (PR) on the upper surface of the oxide film; a-4) forming a pattern on the photoresist by forming a mask having a specific pattern on the board applied with the photoresist and irradiating ultraviolet rays thereon; a-5) forming a pattern on a oxide film by an etching; a-6) removing the photoresist; a-7) forming a pattern on the board by the etching; and a-8) removing the oxide film, wherein in the step a-4), the hollow portion is inclinedly formed by a predetermined angle by controlling an irradiating angle of light.

In the step b), a material of the gas diffusion layer is a form of powder, fiber, or slurry.

Also, as another manufacturing method of a gas diffusion method of the present invention, there is provided a manufacturing method of a gas diffusion layer forming an anode or a cathode of a fuel cell comprising the steps of: i) manufacturing a gas diffusion layer having a predetermined thickness; ii) primarily drying; iii) forming a plurality of hollow portions using a hollow portion forming member formed with a plurality of projections on one side of the gas diffusion layer; and iv) secondarily drying.

Also, the hollow portion forming member is a micro needle or a micro lens.

Meanwhile, the gas diffusion layer of the present invention is manufactured by the foregoing.

Further, the fuel cell of the present invention is formed including the gas diffusion layer.

Thereby, the gas diffusion layer, the manufacturing method thereof, and the fuel cell including the gas diffusion layer manufactured by the method, according to the present invention, use the mold having the specific pattern or form the hollow portion in the gas diffusion layer using the micro needle or the micro lens so that the diffusion resistance inside the gas diffusion layer is lowered, making it possible to smoothly move fuel and reactants through the hollow portion and the reaction is smoothly performed even in a situation where fuel partial pressure is low, making it possible to expect the uniform performance of the fuel cell as well as improve the performance of the fuel cell.

### BRIEF DESCRIPTION OF THE DRAWINGS

FIG. 1 is a photograph showing a general gas diffusion layer.

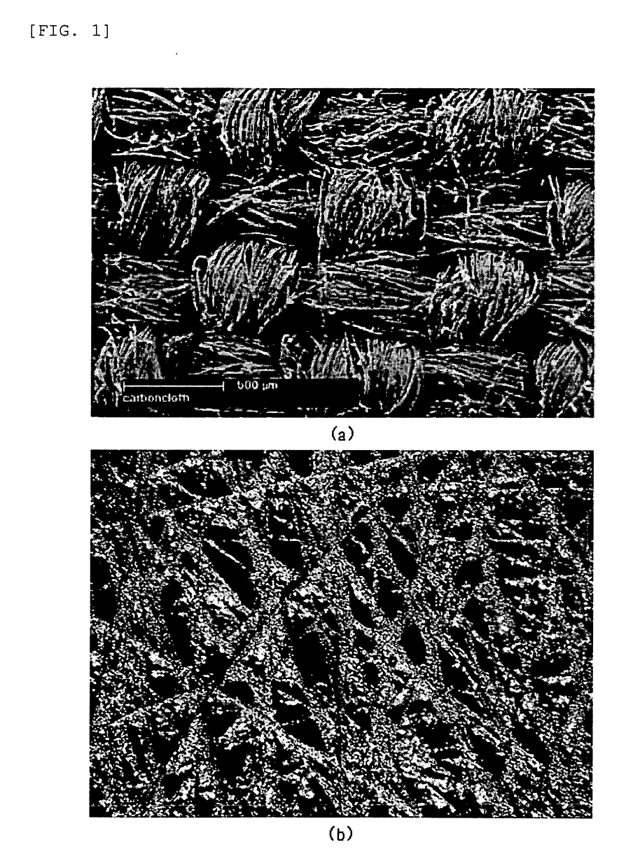

FIG. 2 is a block view of a manufacturing method of a gas diffusion layer according to the present invention.

FIG. 3 is a schematic view showing a manufacture of a gas diffusion layer according to the present invention.

FIG. 4 is a perspective view showing a gas diffusion layer according to the present invention.

FIG. 5 is a block view showing a mold manufacturing step of a manufacturing method of a gas diffusion layer according to the present invention.

FIG. 6 is a schematic view for explaining each step of the block view shown in FIG. 5;

FIG. 7 is another block view of the manufacturing method of the gas diffusion layer according to the present invention.

FIG. 8 is a photograph showing a micro needle of the manufacturing method of the gas diffusion layer according to the present invention.

FIG. 9 is a photograph showing before and after the hollow portion of the gas diffusion layer according to the present invention is formed.

FIG. 10 is a cross-sectional view showing an example of the hollow portion forming member according to the present invention.

FIG. 11 is a schematic view of a cell for a fuel cell according to the present invention.

### DETAILED DESCRIPTION OF MAIN ELEMENTS

Sa˜Sc, S1˜S4, Sa-1˜Sa-8: each step of a manufacturing method of a gas diffusion layerof the present invention

| | |
|---|---|
| 10: mold | 11: board |
| 12: oxide film | 13: photoresist |
| 20: hollow portion forming member | |
| 21: micro needle | |
| 22: micro lens | |
| 23: projection | |
| 30: gas diffusion layer | 31: hollow portion |
| 40: catalyst layer | 50: electrolyte layer |
| 60: anode | 70: cathode |
| 100: cell for fuel cell | |

### BEST MODE FOR CARRYING OUT THE INVENTION

Hereinafter, a gas diffusion layer, a manufacturing method thereof, and a fuel cell including the gas diffusion layer manufactured by the manufacturing method, according to the present invention having the above-mentioned features, will be described with reference to the accompanying drawings.

A gas diffusion layer 30 of the present invention forms hollow portions 31 using various methods to reduce diffusion resistance of material, making it possible to smoothly move fuel and reactants. A method of forming the hollow portion 31 will be described in detail below.

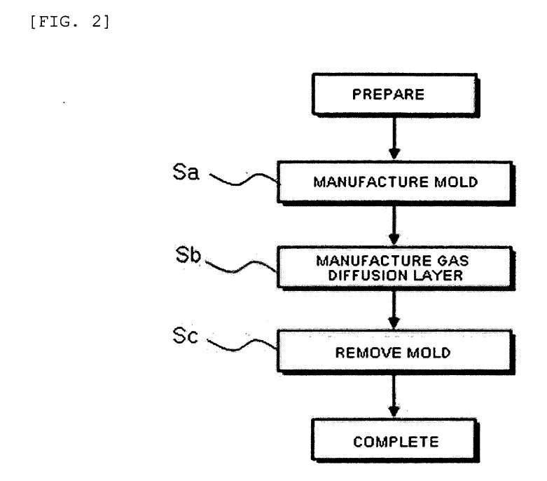

FIG. 2 is a block view of a manufacturing method of a gas diffusion layer according to the present invention. As the manufacturing method of the gas diffusion layer 30 of the present invention, the manufacturing method of the gas diffusion layer forming the anode of the fuel cell comprises the steps of: a) manufacturing (Sa) a mold 10; b) manufacturing (Sb) the gas diffusion layer 30; and c) removing (Sc) the mold 10.

In the manufacturing step (Sa) of the mold 10, the mold 10 has a form corresponding to the hollow portion 31 to form the hollow portion 31 communicated up and down inside the gas diffusion layer 30 and may be formed by various methods.

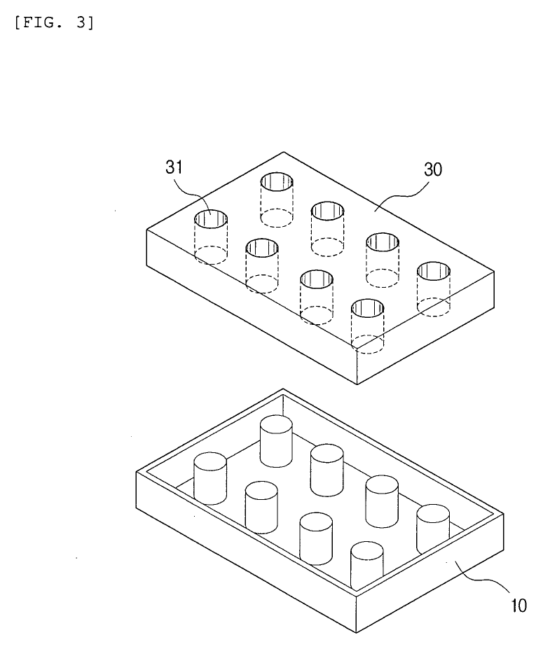

FIG. 3 is a schematic view showing a manufacture of a gas diffusion layer 30 according to the present invention. The gas diffusion layer 30 is manufactured using the manufactured mold 10 to form the gas diffusion layer 30 formed with the hollow portions 31 communicated up and down and the mold 10 is removed, making it possible to manufacture the gas diffusion layer 30.

The diameter and number of hollow portion 31 should be defined in the range without reducing the strength of the gas diffusion layer 30.

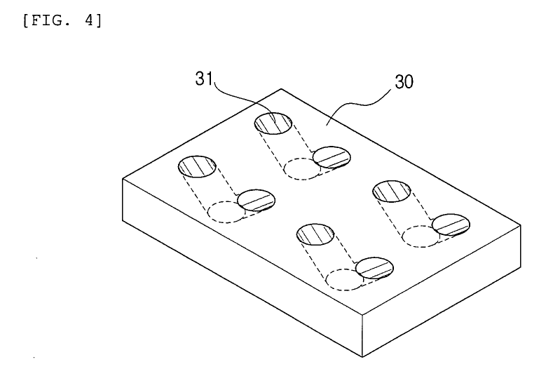

FIG. 4 is a perspective view showing the gas diffusion layer 30 according to the present invention. In the manufacturing method of the gas diffusion layer of the present invention, the hollow portion 31 may be inclinedly formed by a predetermined angle. FIG. 4 shows an example that a pair of left and right hollow portions 31 is formed to be symmetrical with each other. The gas diffusion layer 30 may be formed variously.

The material of the gas diffusion layer 30 uses a form of powder, fiber, or slurry. In the manufacturing step (Sb) of the gas diffusion layer 30, temperature and pressure may be applied, if necessary.

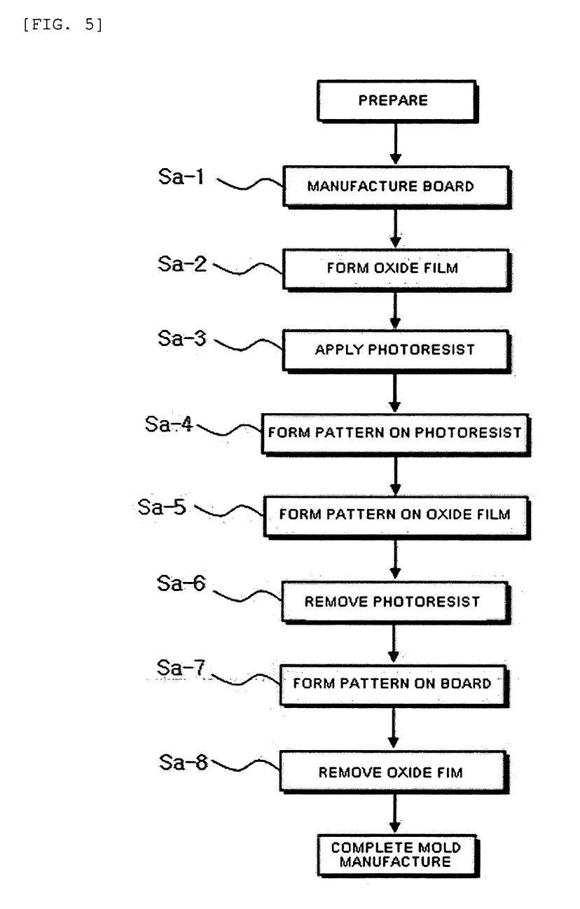

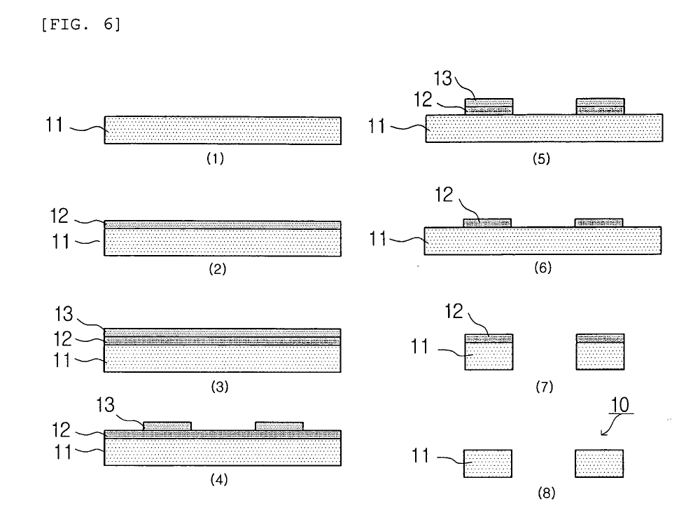

FIG. 5 is a block view showing the mold 10 manufacturing step of the manufacturing method of the gas diffusion layer 30 according to the present invention. FIG. 6 is a schematic view for explaining each step of a block view shown in FIG. 5. A concrete manufacturing method of the mold 10 is proposed.

The manufacturing step (Sa) of the mold 10 includes the steps of: a-1) manufacturing (Sa-1) a board 11 forming the mold 10; a-2) forming (Sa-2) an oxide film 12 on the upper surface of the board 11; a-3) applying (Sa-3) a photoresist 13 on the upper surface of the oxide film 12; a-4) forming (Sa-4) a pattern on the photoresist 13 by forming a mask having a specific pattern and irradiating ultraviolet rays thereon; a-5) forming (Sa-5) a pattern on the oxide film 12; a-6) removing (Sa-6) the photoresist (13); a-7) forming (Sa-7) the pattern on the board 11; and a-8) removing (Sa-8) the oxide film 12.

As the board 11 a silicon wafer may be used, as the oxide film 12 SiO₂ may be used, and as the photoresist 13 Su-8 may be used. Of course, they may be used variously depending on the conditions.

Furthermore, as the photoresist 13 both of a positive photoresist melted by ultraviolet rays and a negative photoresist cured by ultraviolet rays may be used.

In the step (Sa-4) of forming the photoresist 13 pattern, the mask is formed to have the specific pattern so that ultraviolet rays passes through only some regions, thereby forming the specific pattern on the photoresist 13, the oxide film 12, and the board 11.

Also, In the step (Sa-4) of forming the photoresist 13 pattern, the irradiation direction of light is controlled so that the pattern may inclinedly be formed by a predetermined angle.

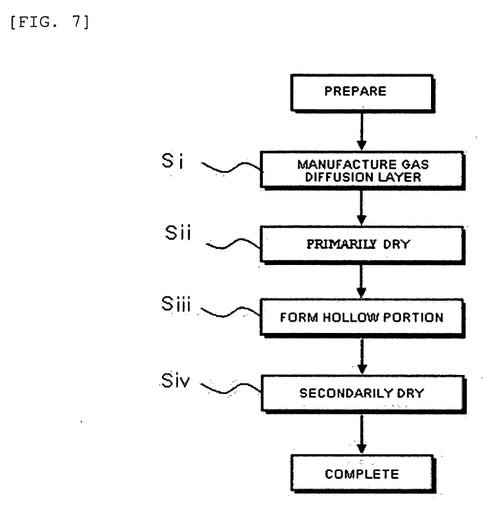

Meanwhile, describing another manufacturing method of the gas diffusion layer 30 formed with the hollow portion 31 with reference to FIG. 7, a manufacturing method of a gas diffusion layer forming the anode or the cathode of the fuel cell comprises the steps of: i) manufacturing (Si) a gas diffusion layer 30 having a predetermined thickness; ii) primarily drying (Sii); iii) forming (Siii) a plurality of hollow portions 31 using a hollow portion forming member 20 formed with a plurality of projections on one side of the gas diffusion layer 30; and iv) secondarily drying (Siv The manufacturing step (Si) of the gas diffusion layer 30 is a step of manufacturing the gas diffusion layer 30 using a material in a form of fiber, slurry, or powder. At this time, pressure may be applied, if necessary.

Preferably, ii) the primarily drying step (Sii), which is a step of drying slurry to have predetermined strength, is performed at a temperature of 150 to 200° C. so that the hollow portion 31 can easily be formed by the hollow portion forming member 20.

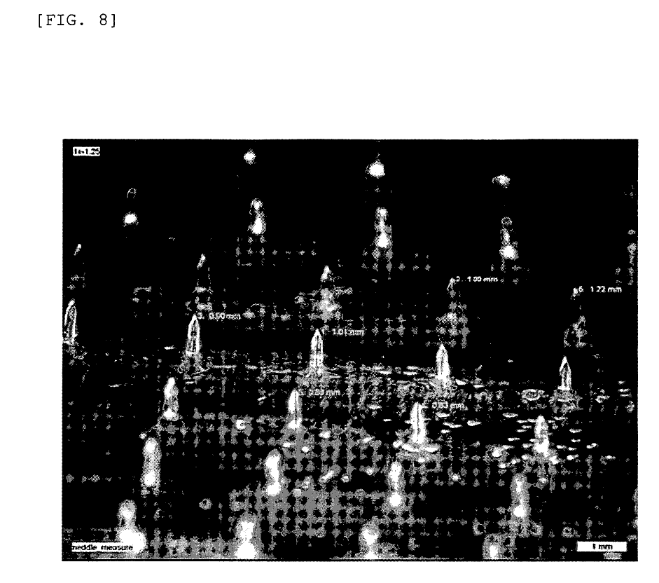

iii) In the step (Siii) of forming the hollow portion 31, the hollow portion forming member 20 may use a micro needle 21 as shown in FIG. 8; however, in addition to the micro needle 21, any components capable of forming the hollow portion 31 formed with a plurality of projections in one side inside a hollow portion forming member 20 may be used without limitation.

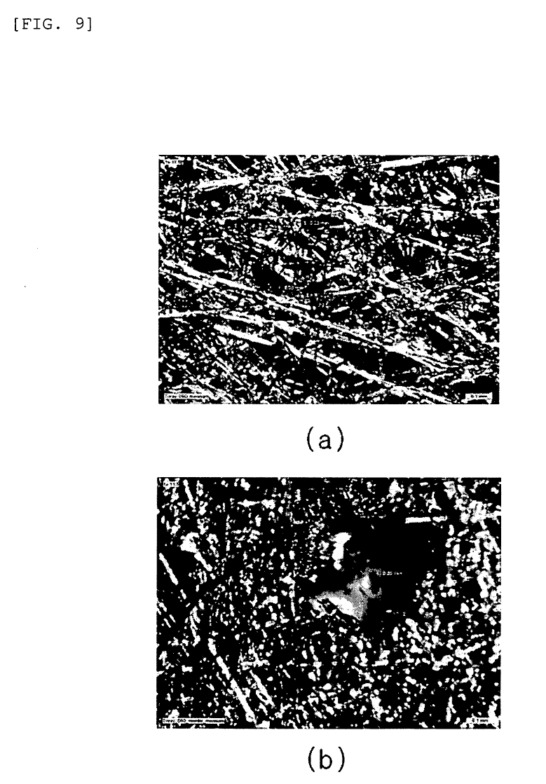

FIG. 9 is a photograph showing before and after the hollow portion 31 of the gas diffusion layer 30 according to the present invention is formed. As shown in FIG. 9, the manufacturing method of the gas diffusion layer of the present invention forms the arranged plurality of hollow portions 31 in the gas diffusion layer 30, thereby obtaining the advantages of the existing porous materials and smoothly moving fuel and byproduct.

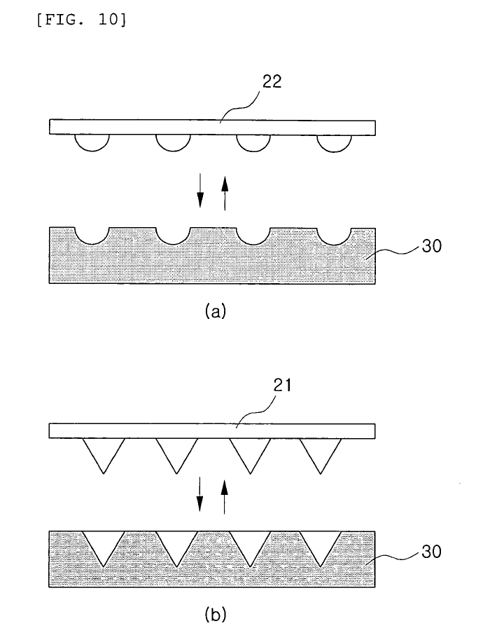

FIG. 10 is a cross-sectional view showing an example of the hollow portion forming member 20 according to the present invention. The micro lens 22 having the projections in a semisphere form as shown in FIG. 10(a) may be used and the micro needle 21 with a different projection shape as shown in FIG. 10(b) may be used.

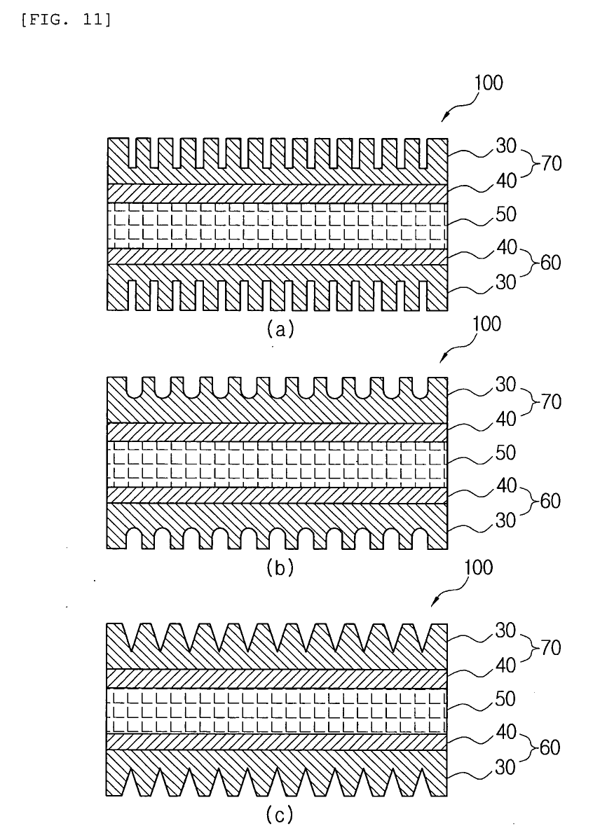

FIG. 11 is a schematic view of a cell 100 for a fuel cell according to the present invention. A cell 100 for a fuel cell according to the present invention comprises an electrolyte layer 50, a catalyst layer 40 and a gas diffusion layer 30 formed to be contacted to both sides of the electrolyte layer 50, an anode 60 contacting hydrogen, and a cathode 70 contacting oxygen and air, cations being transferred through the electrolyte layer 50 or the operating temperature being equal to or less than 100° C., characterized in that the cell 100 for the fuel cell has hollow portions 31 hollowed up and down inside the gas diffusion layer 30.

As a kind of the cell 100 for the fuel cell transferring cations through the electrolyte layer 50 or operated at a temperature of 100° C. or less, there may currently be a direct methanol fuel cell and a polymer electrolyte membrane fuel cell. In the cell 100 for the fuel cell of the present invention, there is water in a liquid phase according to a condition of 100° C. or less, which water can be smoothly discharged through the hollow portion 31.

The hollow portion 31 may be formed variously. In other words, as shown in FIG. 11(a), the hollow portions may be formed in plurality up and down, the hollow portion may be inclinedly formed by a predetermined angle, or the hollow portions 31 may be formed to be communicated with each other.

As described above, the cell 100 for the fuel smoothly supplies fuel through the anode 60 and smoothly performs a removal of moisture formed in the cathode 70 and the anode 60, making it possible to further improve the efficiency of the cell for the fuel cell.

The present invention is not limited to the above-mentioned embodiments and the application range thereof is various as well as those skilled in the art can perform various modifications without departing from the gist of the present invention.

### Embodiment 1

<Manufacture of Gas Diffusion Layer>

After stabilizing a carbon fiber in air atmosphere of a temperature of 230° C. and carbonizing the carbon fiber above 90% of the content of carbon under nitrogen atmosphere of a temperature of 1250 to 1300° C., the carbonized carbon fiber is slurried by mixing binder (polyvinyl alcohol) 10 wt %, dispersant 0.01 wt %, and water 22 wt % based on the weight of carbon fiber.

The slurried carbon fiber is added with phenolic resin 11 wt % and solvent 15 wt % and is then heated at 150° C. and the slurry is raised to a temperature of 175° C. and is then pressurized at 500 kpa, thereby manufacturing the gas diffusion layer 30.

After the manufactured gas diffusion layer 30 is dried for 20 hours at normal temperature, the hollow portion 31 is formed using the micro needle 21 and is dried for 20 hours under nitrogen atmosphere of 2000° C., thereby manufacturing the gas diffusion layer 30.

### INDUSTRIAL APPLICABILITY

Those skilled in the art will appreciate that the conceptions and specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

1. A cell for a fuel cell comprising an electrolyte layer, a catalyst layer and a gas diffusion layer formed to be contacted to both sides of the electrolyte layer, an anode contacting hydrogen, and a cathode contacting oxygen and air, cations being transferred through the electrolyte layer or the operating temperature being equal to or less than 100° C., characterized in that the cell for the fuel cell has hollow portions hollowed up and down inside the gas diffusion layer.

2. The cell according to claim 1, wherein the hollow portion is formed in plurality.

3. The cell according to claim 2, wherein the hollow portion is inclinedly formed by a predetermined angle.

4. The cell according to claim 2, wherein in the cell for the fuel cell, the hollow portions are communicated with each other.

5. A manufacturing method of a gas diffusion layer in a fuel cell comprising the steps of:
a) manufacturing a mold having a form corresponding to a hollow portion to form the hollow portion communicated up and down inside the gas diffusion layer;
b) manufacturing the gas diffusion layer by putting and drying a material of the gas diffusion layer in the mold; and
c) removing the mold.

6. The method according to claim 5, wherein the step a) includes the steps of:
a-1) manufacturing a board forming the mold;
a-2) forming an oxide film on the upper surface of the board 11;
a-3) applying a photoresist (PR) on the upper surface of the oxide film;
a-4) forming a pattern on the photoresist by forming a mask having a specific pattern on the board applied with the photoresist and irradiating ultraviolet rays thereon;
a-5) forming a pattern on the oxide film by an etching;
a-6) removing the photoresist;
a-7) forming a pattern on the board by the etching; and
a-8) removing the oxide film.

7. The method according to claim 6, wherein in the step a-4), the hollow portion is inclinedly formed by a predetermined angle by controlling an irradiating angle of light.

8. The method according to claim 7, wherein in the step b), a material of the gas diffusion layer is a form of powder, fiber, or slurry.

9. A manufacturing method of a gas diffusion layer forming an anode or a cathode of a fuel cell comprising the steps of:
i) manufacturing a gas diffusion layer having a predetermined thickness;
ii) primarily drying;
iii) forming a plurality of hollow portions using a hollow portion forming member formed with a plurality of projections on one side of the gas diffusion layer; and
iv) secondarily drying.

10. The method according to claim 9, wherein the hollow portion forming member is a micro needle or a micro lens.

11. A gas diffusion layer manufactured by the method according to claim 5.

12. A fuel cell including the gas diffusion layer manufactured by claim 11.

13. A gas diffusion layer manufactured by the method according to claim 9.
